(19) United States
(12) Patent Application Publication
(10) Pub. No.: US 2017/0357011 A1
(43) Pub. Date: Dec. 14, 2017

(54) IMAGING PANEL AND X-RAY IMAGING DEVICE

(71) Applicant: Sharp Kabushiki Kaisha, Sakai City, Osaka (JP)

(72) Inventors: KAZUHIDE TOMIYASU, Sakai City (JP); SHIGEYASU MORI, Sakai City (JP)

(73) Assignee: Sharp Kabushiki Kaisha, Sakai City, Osaka (JP)

(21) Appl. No.: 15/541,420

(22) PCT Filed: Dec. 25, 2015
(86) PCT No.: PCT/JP2015/086174

§ 371 Date: Jul. 3, 2017

(30) Foreign Application Priority Data
Jan. 5, 2015 (JP) 2015-000490

(51) Int. Cl. G01T 1/20; H01L 27/146; G01N 23/04

(52) U.S. Cl. CPC G01T 1/20; G01N 23/04; H01L 27/14663

(57) ABSTRACT

An imaging panel (10) is provided that generates an image based on scintillation light obtained from X-ray having passed through an object. The imaging panel (10) includes: a substrate (40); a plurality of conversion elements (15) converting the scintillation light into charges; an insulating film (45, 46) having a plurality of conductive portions (47) that reach the conversion elements (15), respectively; and bias lines (16) formed on the insulating film (45, 46) so as to cover the conductive portions (47), the bias lines (16) being connected to the conversion elements (15) through the conductive portions (47), respectively, and supplying a bias voltage to the conversion elements (15). A dimension of each of the conductive portions (47) in a direction in which the bias lines (16) extend is greater than a dimension of each of the conductive portions (47) in a width direction of the bias lines (16).

### TECHNICAL FIELD

The present invention relates to an imaging panel and an X-ray imaging device.

### BACKGROUND ART

An X-ray imaging device has been known that picks up an X-ray image by using an imaging panel that includes a plurality of pixel portions. In such an X-ray imaging device, X-ray projected thereto is converted into charges by photodiodes. In an indirect-type X-ray imaging device, X-ray projected thereto is converted into scintillation light by a scintillator, and the scintillation light obtained by the conversion is converted by photodiodes into charges. Charges thus obtained by the conversion are read out by causing thin film transistors (hereinafter also referred to as “TFTs”) provided in the pixel portions to operate. Charges are read out in this way, whereby an X-ray image is obtained.

Such an X-ray imaging device is disclosed by, for example, Patent Document 1. In an X-ray imaging device in Patent Document 1, bias lines are electrically connected, through contact holes, with transparent electrodes provided on photodiodes. The contact hole is typically designed in an approximately square shape. The contact hole, designed so that the shape thereof is an approximately square shape, has an actual shape of an approximately circular shape, when viewed in a direction of the normal line of the substrate,

### PRIOR ART DOCUMENT

### Patent Document

Patent Document 1: JP-A-2014-231399

### SUMMARY OF THE INVENTION

### Problem to be Solved by the Invention

Incidentally, in order to ensure that an X-ray imaging device has a large light receiving area, the width of the bias lines may be decreased. When the width of the bias lines is decreased, however, the contact holes provided in the bias lines become smaller, As a result, the areas of contact between the transparent electrodes and the bias lines become smaller, which could lead to a risk that contact resistance would increase. The increase of contact resistance could lead to a risk that signal noises occur to the bias lines, thereby causing an abnormality to occur to the screen display.

It is an object of the present invention to ensure a large light receiving area, while reducing contact resistance between the transparent electrodes and the bias lines.

### Means to Solve the Problem

An imaging panel of the present invention that solves the above-described problem generates an image based on scintillation light obtained from X-ray having passed through an object. The imaging panel includes: a substrate; a plurality of conversion elements formed on the substrate, the conversion elements converting the scintillation light into charges; an insulating film formed so as to cover the conversion elements, the insulating film having a plurality of conductive portions that reach the conversion elements, respectively; and bias lines formed on the insulating film so as to cover the conductive portions, the bias lines being connected to the conversion elements through the conductive portions, respectively, and supplying a bias voltage to the conversion elements. A dimension of each of the conductive portions in a direction in which the bias lines extend is greater than a dimension of each of the conductive portions in a width direction of the bias lines.

### Effect of the Invention

With the present invention, it is possible to ensure a large light receiving area, while reducing contact resistance between the transparent electrodes and the bias lines.

### BRIEF DESCRIPTION OF DRAWINGS

FIG. 1 is a schematic diagram illustrating an X-ray imaging device in Embodiment 1.

FIG. 2 is a schematic diagram illustrating a schematic configuration of the imaging panel illustrated in FIG. 1.

FIG. 3A is a plan view of a pixel of the imaging panel illustrated in FIG. 2.

FIG. 3B is an enlarged plan view of the vicinities of the second contact hole illustrated in FIG. 3A.

FIG. 4A is a cross-sectional view of the pixel illustrated in FIG. 3A taken along the line A-A.

FIG. 4B is a cross-sectional view of the pixel illustrated in FIG. 3A taken along the line B-B.

FIG. 5 illustrates the A-A cross section and the B-B cross section of the gate electrode of the pixel illustrated in FIG. 3A in a producing process.

FIG. 6 illustrates the A-A cross section and the B-B cross section of the gate insulating film of the pixel illustrated in FIG. 3A in the producing process.

FIG. 7 illustrates the A-A cross section and the B-B cross section of the semiconductor active layer of the pixel illustrated in FIG. 3A in the producing process.

FIG. 8 illustrates the A-A cross section and the B-B cross section of the source electrode and the drain electrode of the pixel illustrated in FIG. 3A in the producing process.

FIG. 9 illustrates the A-A cross section and the B-B cross section of the photodiode and the electrode of the pixel illustrated in FIG. 3A in the producing process.

FIG. 10A illustrates the A-A cross section and the B-B cross section of the second interlayer insulating film and the photosensitive resin layer of the pixel illustrated in FIG. 3A in the producing process.

FIG. 10B is a diagram for explaining the shape of the second contact hole.

FIG. 10C is a diagram for explaining the shape of the second contact hole.

FIG. 11 illustrates the A-A cross section and the B-B cross section of the bias line of the pixel illustrated in FIG. 3A in the producing process.

FIG. 12 is a plan view illustrating a pixel of an imaging panel according to a modification example of Embodiment 1.

FIG. 13 is a plan view illustrating a pixel of an imaging panel according to a modification example of Embodiment 1.

FIG. 14 is a plan view illustrating a pixel of an imaging panel according to Embodiment 2.

FIG. 15 is a plan view illustrating a pixel of an imaging panel according to Embodiment 3.

FIG. 16 is a cross-sectional view of a pixel of an imaging panel that includes a top gate type TFT in a modification example.

FIG. 17 is a cross-sectional view of a pixel of an imaging panel that includes a TFT having an etching stopper layer, in a modification example.

### MODE FOR CARRYING OUT THE INVENTION

An imaging panel according to the present invention generates an image based on scintillation light obtained from X-ray having passed through an object. The imaging panel includes: a substrate; a plurality of conversion elements formed on the substrate, the conversion elements converting the scintillation light into charges; an insulating film formed so as to cover the conversion elements, the insulating film having a plurality of conductive portions that reach the conversion elements, respectively; and bias lines formed on the insulating film so as to cover the conductive portions, the bias lines being connected to the conversion elements through the conductive portions, respectively, and supplying a bias voltage to the conversion elements. A dimension of each of the conductive portions in a direction in which the bias lines extend is greater than a dimension of each of the conductive portions in a width direction of the bias lines (the first configuration).

In the imaging panel of the first configuration, the bias lines and the conversion elements are electrically connected through the conductive portions formed in the insulating film, and the dimension of each conductive portion in the direction in which the bias lines extend is greater than the dimension thereof in the width direction of the bias lines. A larger area, therefore, can be ensured for each conductive portion, as compared with the case where the dimension of each conductive portion in the extending direction and the direction thereof in the width direction are substantially equal. The increase of the area of the conductive portion leads to the reduction of the contact resistance between the bias line and the conversion element even in a case where the bias lines have a smaller width, and as a result, the occurrence of signal noises in the bias lines can be suppressed. This therefore makes it possible to suppress the occurrence of an abnormality to the screen display of the imaging panel.

The second configuration is the first configuration further characterized in that; each of the conductive portions is formed with a contact hole in an approximately elliptical shape when viewed in a direction of a normal line of the substrate; and a long axis of the elliptical shape of the contact hole is along the direction in which the bias lines extend, and a short axis of the elliptical shape thereof is along the width direction of the bias lines.

According to the second configuration, the bias lines and the conversion elements are electrically connected through the contact holes each of which is in an approximately elliptical shape. This makes it possible to ensure larger contact areas therebetween, as compared with a case where they are electrically connected through contact holes each of which is in an approximately perfect circular shape.

The third configuration is the second configuration further characterized in that a dimension of the long axis of the elliptical shape of the contact hole is greater than a width direction dimension of the bias line in which the conductive portion is provided.

According to the third configuration, the dimension of the long axis of the elliptical shape is greater than the width direction dimension of the bias line. This therefore makes it possible to sufficiently ensure the contact areas between the bias lines and the conversion elements.

The fourth configuration is the first configuration further characterized in that each of the conductive portions is formed with a long opening that extends along the bias lines, and at the same time, has a width smaller than the width of each bias line.

According to the fourth configuration, the bias lines and the conversion elements are electrically connected through long openings each of which extends along the bias line, and at the same time, has a width smaller than the width of each bias line. This therefore makes it possible to ensure larger contact areas.

The fifth configuration is the first configuration further characterized in that each of the conductive portions is formed with a plurality of contact holes arranged so as to be arrayed along the direction in which the bias lines extend.

According to the fifth configuration, the bias lines and the conversion elements are electrically connected through a plurality of contact holes arranged so as to be arrayed along the direction in which the bias lines extend, This therefore makes it possible to ensure larger contact areas, as compared with a case where each pair is electrically connected through a single contact hole.

An X-ray imaging device of the present invention includes: the imaging panel having a configuration according to any one of the first to fifth configurations; a control unit that reads out a data signal corresponding to charges obtained by conversion by each of the conversion elements; an X-ray source that emits X-ray; and a scintillator that convers the X-ray into scintillation light (the sixth configuration).

The sixth configuration includes an imaging panel in which the contact resistances between the bias lines and the conversion elements are reduced. This therefore makes it possible to suppress the occurrence of an abnormality to the screen display of the X-ray imaging device.

The following describes embodiments of the present invention in detail, while referring to the drawings. Identical or equivalent parts in the drawings are denoted by the same reference numerals, and the descriptions of the same are not repeated.

### EMBODIMENT 1

### Configuration

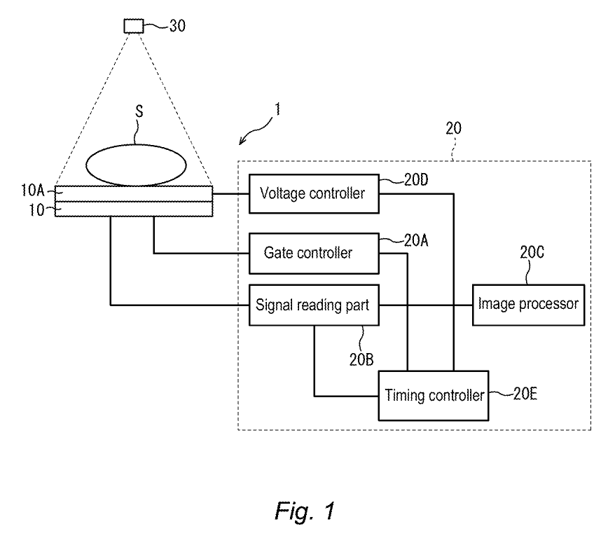

FIG. 1 is a schematic diagram illustrating an X-ray imaging device in an embodiment. The X-ray imaging device 1 includes an imaging panel 10 and a control unit 20. X-ray is projected from an X-ray source 30 to an object S, and X-ray having passed through the object S is converted into fluorescence (hereinafter referred to as scintillation light) by a scintillator 10A arranged above the imaging panel 10. The X-ray imaging device 1 obtains an X-ray image by picking up the scintillation light with use of the imaging panel 10 and the control unit 20.

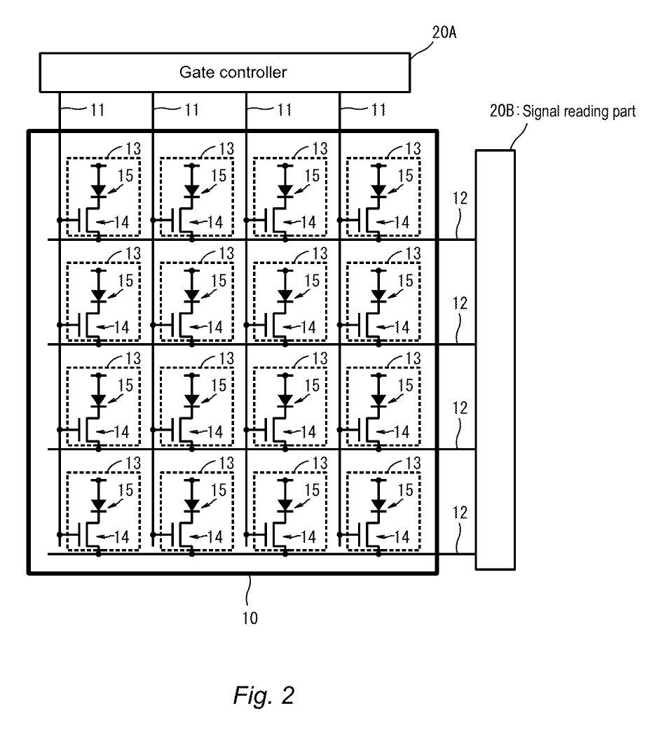

FIG. 2 is a schematic diagram illustrating a schematic configuration of the imaging panel 10. As illustrated in FIG. 2, a plurality of gate lines 11 and a plurality of data lines 12 that intersect with the gate lines 11 are formed in the imaging panel 10. The imaging panel 10 includes a plurality of pixels 13 that are defined by the gate lines 11 and the data line 12. FIG. 2 illustrates an example in which sixteen pixels 13 (four rows by four columns) are provided, but the number of pixels in the imaging panel 10 is not limited to this.

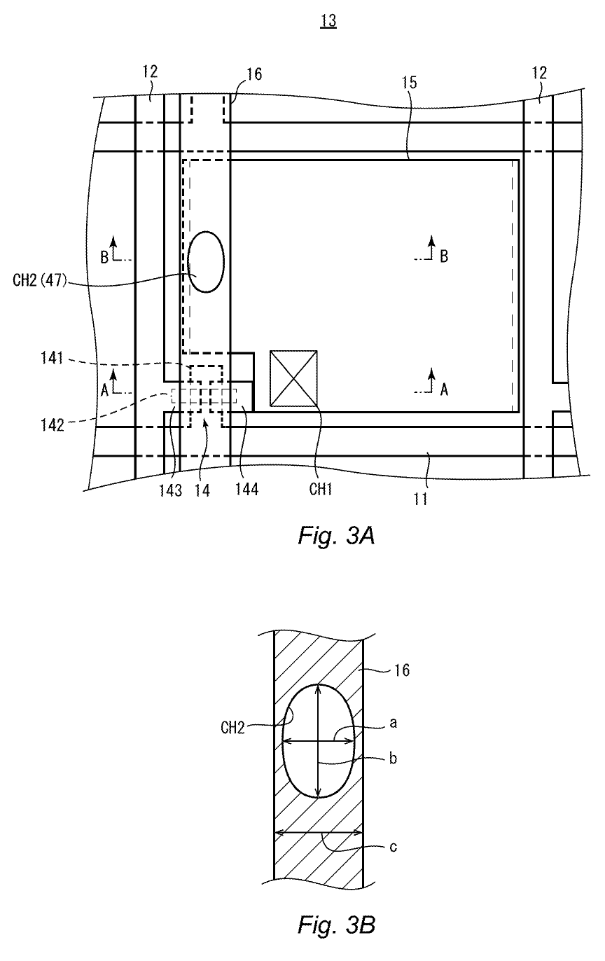

Each pixel 13 is provided with a TFT 14 connected to the gate line 11 and the data line 12, and a conversion element connected to the TFT 14. The conversion element includes a photodiode 15, and an electrode 44 provided on the photodiode 15. Further, though the illustration is omitted in FIG. 2, each pixel 13 is provided with a bias line 16 (see FIG. 3A) for supplying a bias voltage to the photodiode 15, so that the bias line 16 is approximately parallel to the data line 12.

In each pixel 13, scintillation light obtained by converting X-ray having passed through the object S is converted by the photodiode 15 into charges in accordance with the amount of the light.

The gate lines 11 in the imaging panel 10 are switched sequentially to a selected state one by one by a gate controller 20A, and the TFTs 14 connected to the gate line 11 in the selected state are turned ON. When the TFTs 14 shift to the ON state, data signals corresponding to charges obtained by conversion by the photodiode 15 are output to the data lines 12.

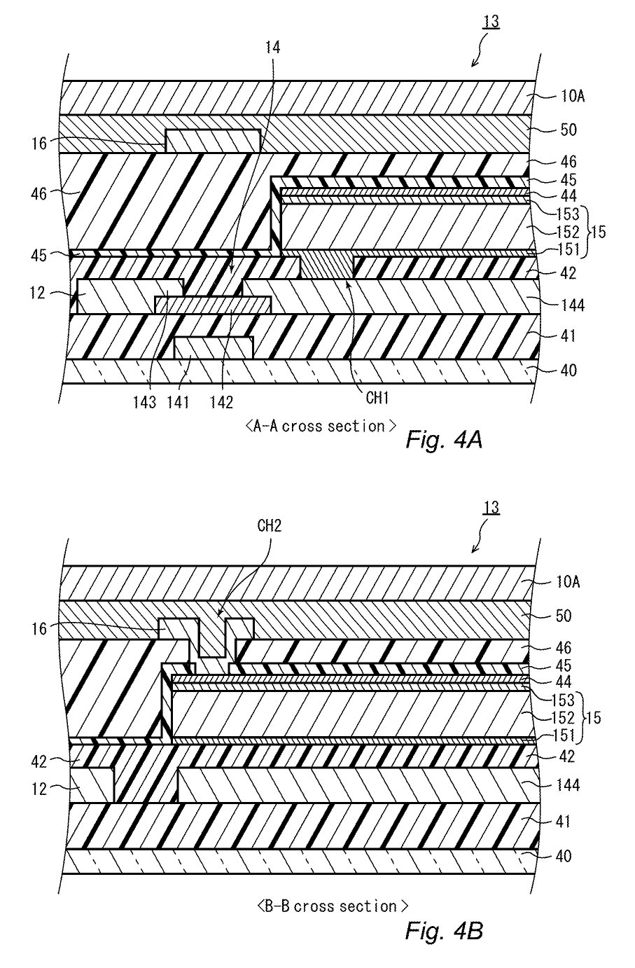

Next, the following description describes a specific configuration of the pixel 13. FIG. 3A is a plan view illustrating the pixel 13 of the imaging panel 10 illustrated in FIG. 2. Further, FIG. 4A is a cross-sectional view of the pixel 13 illustrated in FIG. 3A taken along the line A-A, and FIG. 4B is a cross-sectional view of the pixel 13 illustrated in FIG. 3A taken along the line B-B.

As illustrated in FIGS. 4A and 4B, the pixel 13 is formed on a substrate 40. The substrate 40 is a substrate having insulating properties, such as a glass substrate, a silicon substrate, a plastic substrate having heat-resisting properties, or a resin substrate. In particular, polyethylene terephthalate (PET), polyethylene naphthalate (PEN), polyether sulfone (PES), acryl, polyimide, or the like may be used for a plastic substrate or a resin substrate.

The TFT 14 includes a gate electrode 141, a semiconductor active layer 142 arranged on the gate electrode 141 with a gate insulating film 41 being interposed therebetween, and a source electrode 143 as well as a drain electrode 144 connected to the semiconductor active layer 142.

The gate electrode 141 is formed in contact with a surface of the substrate 40, the surface being one of the surfaces in the thickness direction (hereinafter referred to as a principal surface). The gate electrode 141 is made of, for example, a metal such as aluminum (Al), tungsten (W), molybdenum (Mo), tantalum (Ta), chromium (Cr), titanium (Ti), or copper (Cu), an alloy of any of these metals, or a nitride of any of these metals. Further, the gate electrode 141 may be, for example, a laminate of a plurality of metal films. In the present embodiment, the gate electrode 141 has a laminate structure in which a metal film made of aluminum, and a metal film made of titanium are laminated in the stated order.

As illustrated in FIG. 4A, the gate insulating film 41 is formed on the substrate 40, covering the gate electrode 141. To form the gate insulating film 41, for example, silicon oxide (SiOₓ), silicon nitride (SiNₓ), silicon oxide nitride (SiOₓN_{y}) (x>y), silicon nitride oxide (SiNₓO_{y}) (x>y), or the like, may be used.

In order to prevent diffusion of impurities and the like from the substrate 40, the gate insulating film 41 may have a laminate structure. For example, silicon nitride (SiNₓ), silicon nitride oxide (SiNₓO_{y}) (x>y), or the like may be used in a lower layer; and silicon oxide (SiOₓ), silicon oxide nitride (SiOₓN_{y}) (x>y), or the like may be used in an upper layer. Further, in order that a fine gate insulating film that allows a smaller gate leakage current is formed at a low film forming temperature, a noble gas element such as argon may be contained in a reaction gas so as to be included in the insulating film. In the present embodiment, the gate insulating film 41 has a laminate structure that includes, in the lower layer, a silicon nitride film having a film thickness of 100 nm to 400 nm, which is formed with use of SiH₄ or NH₃ as a reaction gas, and in the upper layer, a silicon oxide film having a film thickness of 50 to 100 nm.

As illustrated in FIG. 4A, the semiconductor active layer 142 is formed in contact with the gate insulating film 41. The semiconductor active layer 142 is formed with an oxide semiconductor. As the oxide semiconductor, for example, the following may be used; an amorphous oxide semiconductor or the like containing lnGaO₃(ZnO)₅, magnesium zinc oxide (MgₓZn₁₋ₓO), cadmium zinc oxide (CdₓZn₁₋ₓO), cadmium oxide (CdO), or, indium (In), as well as gallium (Ga) and zinc (Zn), at a predetermined ratio. Further, for the semiconductor active layer 142, the following may be used: ZnO in an amorphous state to which one type or several types of impurities elements among elements of Group I, elements of Group XIII, elements of Group XIV, elements of Group XV, elements of Group XVII, and the like are added; or alternatively, such ZnO in a polycrystalline state. Further alternatively, ZnO in a microcrystalline state in which ZnO in an amorphous state and ZnO in a polycrystalline state are mixed, or ZnO in which no impurities element is added, may be used.

The source electrode 143 and the drain electrode 144 are formed in contact with the semiconductor active layer 142 and the gate insulating film 41, as illustrated in FIGS. 4A and 4B. As illustrated in FIG. 3A, the source electrode 143 is connected to the data line 12. As illustrated in FIG. 4A, the drain electrode 144 is connected to the photodiode 15 through the first contact hole CH1. The source electrode 143, the data line 12, and the drain electrode 144 are formed in the same layer.

The source electrode 143, the data line 12, and the drain electrode 144 are made of a metal such as aluminum (Al), tungsten (W), molybdenum (Mo), tantalum (Ta), chromium (Cr), titanium (Ti), copper (Cu) or the like, or an alloy of any of these, or nitride of any of these metals. Further, as a material for the source electrode 143, the data line 12, and the drain electrode 144, the following may be used; a material having translucency such as indium tin oxide (ITO), indium zinc oxide (IZO), indium tin oxide (ITSO) containing silicon oxide, indium oxide (In₂O₃), tin oxide (SnO₂), zinc oxide (ZnO), or titanium nitride; or an appropriate combination of any of these.

The source electrode 143, the data line 12, and the drain electrode 144 may be obtained by, for example, laminating a plurality of metal films. In the present embodiment, the source electrode 143, the data line 12, and the drain electrode 144 have a laminate structure obtained by laminating a metal film made of titanium, a metal film made of aluminum, and a metal film made of titanium in this order.

As illustrated in FIGS. 4A and 4B, the first interlayer insulating film 42 covers the semiconductor active layer 142, the source electrode 143, the data line 12, and the drain electrode 144. The first interlayer insulating film 42 may have a single layer structure made of silicon oxide (SiO₂) or silicon nitride (SiN), or a laminate structure obtained by laminating silicon nitride (SiN) and silicon oxide (SiO₂) in this order.

As illustrated in FIGS. 4A and 4B, the photodiode 15 is formed on the first interlayer insulating film 42, so as to be in contact with the drain electrode 144. The photodiode 15 includes, at least, a first semiconductor layer having a first conductivity, and a second semiconductor layer having a second conductivity that is opposite to the first conductivity. In the present embodiment, the photodiode 15 includes an n-type amorphous silicon layer 151 (first semiconductor layer), an intrinsic amorphous silicon layer 152, and a p-type amorphous silicon layer 153 (second semiconductor layer).

The n-type amorphous silicon layer 151 is made of amorphous silicon doped with n-type impurities (for example, phosphorus). The n-type amorphous silicon layer 151 is formed in contact with the drain electrode 144. The n-type amorphous silicon layer 151 has a thickness of, for example, 20 to 100 nm.

The intrinsic amorphous silicon layer 152 is made of intrinsic amorphous silicon. The intrinsic amorphous silicon layer 152 is formed in contact with the n-type amorphous silicon layer 151. The intrinsic amorphous silicon layer has a thickness of, for example, 200 to 2000 nm.

The p-type amorphous silicon layer 153 is made of amorphous silicon doped with p-type impurities (for example, boron). The p-type amorphous silicon layer 153 is formed in contact with the intrinsic amorphous silicon layer 152. The p-type amorphous silicon layer 153 has a thickness of, for example, 10 to 50 nm.

The drain electrode 144 functions as a drain electrode of the TFT 14, and at the same time, functions as a lower electrode of the photodiode 15. Further, the drain electrode 144 also functions as a reflection film that reflects scintillation light having passed through the photodiode 15, toward the photodiode 15.

As illustrated in FIGS. 4A and 4B, the electrode 44 is formed on the photodiode 15, and functions as an upper electrode of the photodiode 15. The electrode 44 is made of, for example, indium zinc oxide (IZO).

The second interlayer insulating film 45 is formed in contact with the first interlayer insulating film 42 and the electrode 44. The second interlayer insulating film 45 may have a single layer structure made of silicon oxide (SiO₂) or silicon nitride (SiN), or a laminate structure obtained by laminating silicon nitride (SiN) and silicon oxide (SiO₂) in this order.

A photosensitive resin layer 46 is formed on the second interlayer insulating film 45. The photosensitive resin layer 46 is made of an organic resin material, or an inorganic resin material.

In the second interlayer insulating film 45 and the photosensitive resin layer 46, as illustrated in FIG. 3A, a second contact hole CH2 is formed in each of the pixels 13. The second contact hole CH2 is arranged in the vicinity of the TFT 14, so as to overlap the bias line 16 to be described below. The second contact hole CH2 is a conductive portion 47 for electrically connecting the electrode 44 and the bias line 16.

FIG. 3B is a plan view that illustrates the second contact hole CH2 in an enlarged state. As illustrated in FIG. 3B, the second contact hole CH2 has an approximately elliptical shape when viewed in the direction of the normal line of the substrate 40. The long axis of the elliptical shape of the second contact hole CH2 is along the direction in which the bias line 16 extends. Further, the short axis of the elliptical shape of the second contact hole CH2 is along the width direction of the bias line 16. “a” (minor axis a) representing the length of the short axis of the second contact hole CH2, “b” (major axis b) representing the length of the long axis thereof, and “c” representing the width of the bias line 16 satisfy the relationship expressed by Formula (1) below:

a<c<b (1)

Further, the ratio among “a” (minor axis a) representing the length of the short axis of the second contact hole CH2, “b” (major axis b) representing the length of the long axis thereof, and “c” representing the width of the bias line 16, can be set so as to satisfy, for example, a:b:c=2:3:4.

As illustrated in FIGS. 3A, 4A, and 4B, the bias line 16 is formed on the photosensitive resin layer 46, so as to be approximately in parallel to the data line 12. The bias line 16 is connected to a voltage controller 20D (see FIG. 1), Further, as illustrated in FIG. 4B, the bias line 16 is connected to the electrode 44 through the second contact hole CH2, so as to apply a bias voltage supplied from the voltage controller 20D to the electrode 44. The bias line 16 has a laminate structure obtained by laminating, for example, indium zinc oxide (IZO) and molybdenum (Mo).

As illustrated in FIGS. 4A and 4B, on the imaging panel 10, that is, on the photosensitive resin layer 46, a protection layer 50 is formed so as to cover the bias line 16, and the scintillator 10A is provided on the protection layer 50.

Referring to FIG. 1 again, the following describes the configuration of the control unit 20, The control unit 20 includes the gate controller 20A, a signal reading part 20B, an image processor 20C, the voltage controller 20D, and a timing controller 20E.

As illustrated in FIG. 2, a plurality of the gate lines 11 are connected to the gate controller 20A. The gate controller 20A applies a predetermined gate voltage, through the gate lines 11, to the TFTs 14 that the pixels 13 connected to the gate lines 11 include.

As illustrated in FIG. 2, a plurality of the data lines 12 are connected to the signal reading part 20B. Through the respective data lines 12, the signal reading part 20B reads out data signals corresponding to charges obtained by conversion by the photodiodes 15 that the pixels 13 include. The signal reading part 20B generates image signals based on the data signals, and outputs the same to the image processor 20C.

The image processor 20C generates an X-ray image signal based on the image signals output from the reading part 20B.

The voltage controller 20D is connected to the bias lines 16. The voltage controller 20D applies a predetermined bias voltage to the bias lines 16. This allows a bias voltage to be applied to the photodiodes 15 through the electrodes 44 connected to the bias lines 16.

The timing controller 20E controls timings of operations of the gate controller 20A, the signal reading part 20B, and the voltage controller 20D.

The gate controller 20A selects one gate line 11 from among a plurality of the gate lines 11, based on the control signal from the timing controller 20E. The gate controller 20A applies a predetermined gate voltage, through the selected gate line 11, to the TFTs 14 that the pixels 13 connected to the selected gate line 11 include.

The signal reading part 20B selects one data line 12 from among a plurality of the data lines 12 based on the control signal from the timing controller 20E. Through the selected data line 12, the signal reading part 20B reads out a data signal corresponding to charges obtained by conversion by the photodiode 15 in the pixel 13. The signal reading part 20B reads out the data signal corresponding to charges obtained by conversion by the photodiode 15 in the pixel 13, through the selected data line 12. The pixel 13 from which a data signal is read out is connected to the data line 12 selected by the signal reading part 20B, and is connected to the gate line 11 selected by the gate controller 20A.

The timing controller 20E, for example, outputs a control signal to the voltage controller 20D when X-ray is emitted from the X-ray source 30. Based on this control signal, the voltage controller 20D applies a predetermined bias voltage to the electrode 44.

### Operation of X-ray Imaging Device 10

First, X-ray is emitted by the X-ray source 30. Here, the timing controller 20E outputs a control signal to the voltage controller 20D. More specifically, for example, a signal that indicates that X-ray is emitted from the X-ray source 30 is output from the control device that controls operations of the X-ray source 30, to the timing controller 20E. When this signal is input to the timing controller 20E, the timing controller 20E outputs the control signal to the voltage controller 20D. The voltage controller 20D applies a predetermined voltage (bias voltage) to the bias line 16 based on the control signal from the timing controller 20E.

The X-ray emitted from the X-ray source 30 passes through the object S, and becomes incident on the scintillator 10A. The X-ray incident on the scintillator 10A is converted to fluorescence (scintillation light), and the scintillation light becomes incident on the imaging panel 10.

When the scintillation light becomes incident on the photodiode 15 provided in each pixel 13 in the imaging panel 10, the scintillation light is converted by the photodiode 15 into charges corresponding to the amount of the scintillation light.

A data signal corresponding to the charges obtained by conversion by the photodiode 15 is read out by the signal reading part 20B through the data line 12 when the TFT 14 is caused to be in an ON state in response to a gate voltage (positive voltage) that is output from the gate controller 20A through the gate line 11. An X-ray image corresponding to the data signal thus read out is generated by the image processor 20C.

### Method for Producing Imaging Panel 10

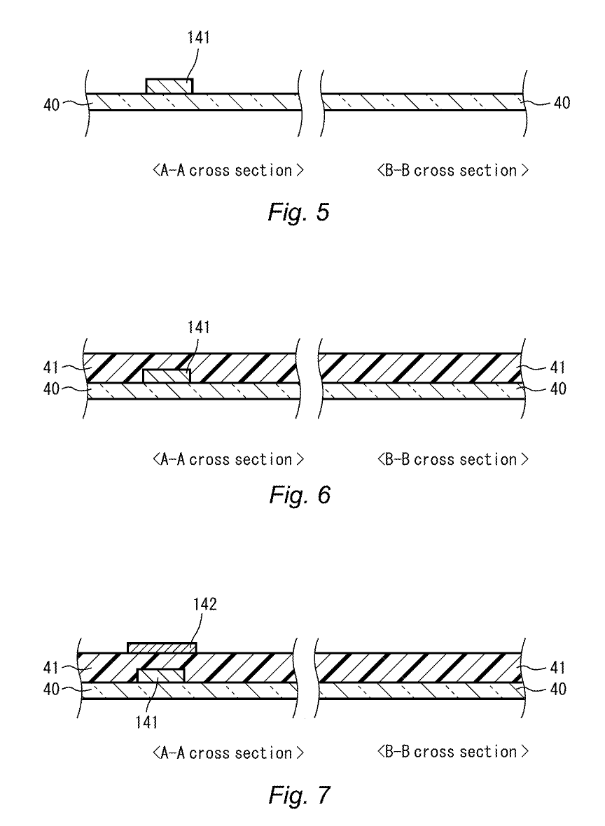

Next, the following describes a method for producing the imaging panel 10. FIGS. 5 to 11 illustrate an A-A cross-sectional view and a B-B cross-sectional view of the pixel 13 in each step of the method for producing the imaging panel 10.

As illustrated in FIG. 5, a metal film is formed on the substrate 40, which is obtained by laminating aluminum and titanium by sputtering or the like. Then, this metal film is patterned by photolithography, whereby the gate electrode 141 and the gate line 11 (not shown in FIG. 5) are formed. This metal film has a thickness of, for example, 300 nm.

Next, as illustrated in FIG. 6, the gate insulating film 41 made of silicon oxide (SiOₓ), silicon nitride (SiNₓ), or the like is formed on the substrate 40 by plasma CVD, sputtering, or the like, so as to cover the gate electrode 141. The gate insulating film 41 has a thickness of, for example, 20 to 150 nm.

Subsequently, as illustrated in FIG. 7, a film of oxide semiconductor is formed on the gate insulating film 41 by, for example, sputtering or the like, and the oxide semiconductor is patterned by photolithography, whereby the semiconductor active layer 142 is formed. After the semiconductor active layer 142 is formed, it may be subjected to heat treatment in an atmosphere containing oxygen (for example, in the ambient atmosphere) at a high temperature (for example, at 350° C. or higher). In this case, oxygen defects in the semiconductor active layer 142 can be decreased. The semiconductor active layer 142 has a thickness of, for example, 30 to 100 nm.

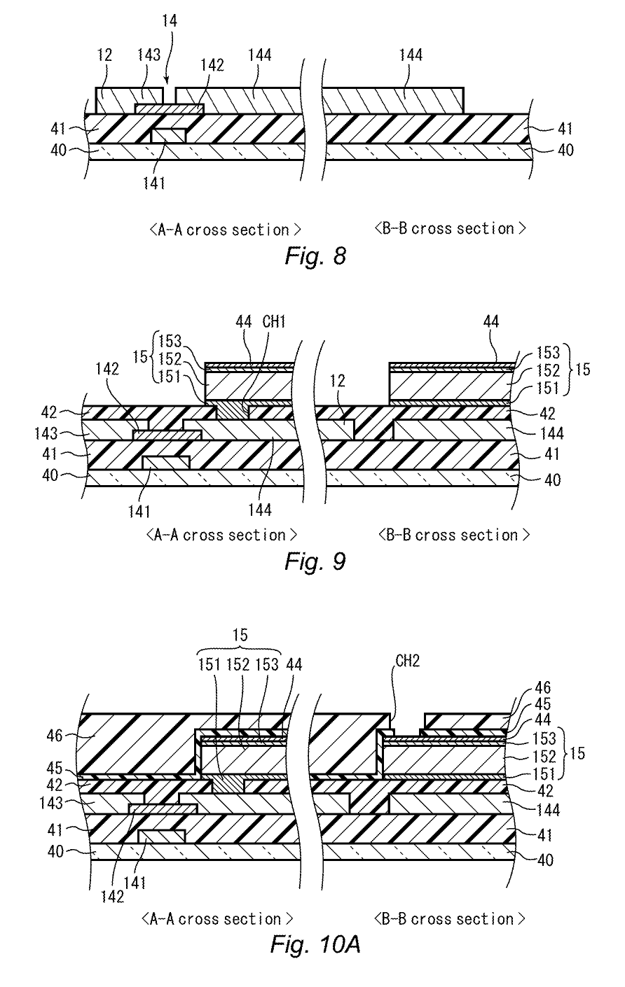

Next, as illustrated in FIG. 8, a metal film obtained by laminating titanium, aluminum, and titanium in this order is formed on the gate insulating film 41, and on the semiconductor active layer 142, by sputtering or the like. Then, this metal film is patterned by photolithography, whereby the source electrode 143, the data line 12, and the drain electrode 144 are formed. The thickness of the source electrode 143, the data line 12, and the drain electrode 144 is, for example, 50 to 500 nm. The etching processing may be dry etching or wet etching, but in a case where the substrate 40 has a large area, dry etching is suitable. Thereby, the bottom gate type TFT 14 is formed.

Subsequently, as illustrated in FIG. 9, the first interlayer insulating film 42 made of silicon oxide (SiO₂) or silicon nitride (SiN) is formed by, for example, plasma CVD, on the source electrode 143, the data line 12, the drain electrode 144. Then, a heat treatment at about 350° C. is applied to an entire surface of the substrate 40, and the first interlayer insulating film 42 is patterned by photolithography, whereby the first contact hole CH1 is formed.

Next, as illustrated in FIG. 9, films are formed in the order of the n-type amorphous silicon layer 151, the intrinsic amorphous silicon layer 152, and the p-type amorphous silicon layer 153, by sputtering or the like on the first interlayer insulating film 42 and the drain electrode 144. Here, though the first contact hole CH1, the drain electrode 144 and the n-type amorphous silicon layer 151 are electrically connected with each other. Then, patterning by photolithography is performed, followed by dry etching, whereby the photodiode 15 is formed.

Subsequently, a film of indium zinc oxide (IZO) is formed by sputtering or the like on the first interlayer insulating film 42 and the photodiode 15, and the film is patterned by photolithography, whereby the electrode 44 is formed.

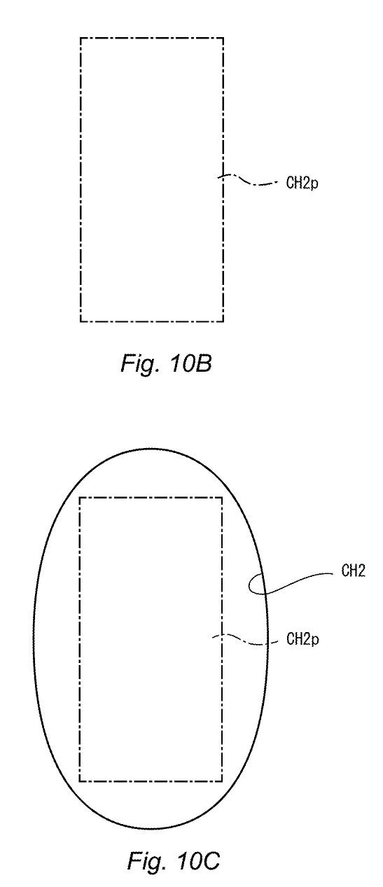

Next, as illustrated in FIG. 10A, a film of silicon oxide (SiO₂) or silicon nitride (SiN) is formed on the first interlayer insulating film 42 and the electrode 44 by plasma CVD or the like, whereby the second interlayer insulating film 45 is formed. Then, the film is patterned by photolithography, whereby an opening that is to become the second contact hole CH2 is formed above the electrode 44.

Subsequently, as illustrated in FIG. 10A, a film of a photosensitive resin is formed on the second interlayer insulating film 45, and is dried, whereby the photosensitive resin layer 46 is formed. Further, an opening is formed by photolithography. This allows the second contact hole CH2 to be obtained that passes through the second interlayer insulating film 45 and the photosensitive resin layer 46. Here, as illustrated in FIG. 10B, in a case where an area denoted by “CH2p” is etched as a contact hole forming area CH2p, an area of an outer circumference of the contact hole forming area CH2p is etched together, and a second contact hole CH2 in an elliptical shape is formed, as illustrated in FIG. 10C.

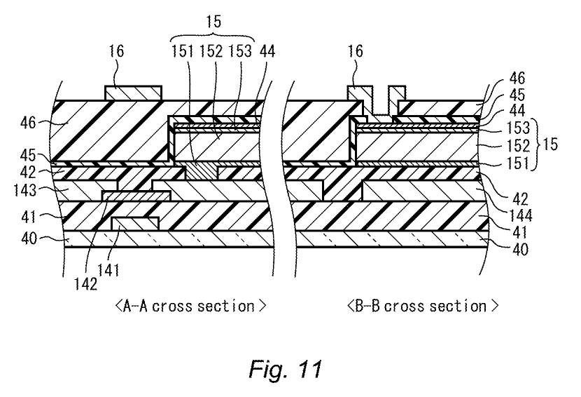

Further, as illustrated in FIG. 11, a metal film is formed on the photosensitive resin layer 46, the metal film being obtained by laminating indium zinc oxide (IZO) and molybdenum (Mo) by sputtering or the like. The film is patterned by photolithography, whereby the bias line 16 is formed.

In the present embodiment, since the dimension in the direction in which the bias line 16 extends, of the conductive portion 47 (second contact hole CH2) that electrically connects the bias line 16 and the electrode 44 with each other, is greater than the dimension thereof in the width direction of the bias line 16, a large area can be ensured for the conductive portion 47 (second contact hole CH2). An increase in the area for the conductive portion 47 (second contact hole CH2) allows a contact resistance between the bias line 16 and the electrode 44 to be reduced even in a case where the width of the bias line 16 is small, which, as a result, makes it possible to suppress the occurrence of signal noises to the bias line 16. This therefore makes it possible to suppress the occurrence of an abnormality to the screen display of the imaging panel 10.

### Modification Example of Embodiment 1

In the description of Embodiment 1, it is described that the following formula (1) is satisfied regarding the relationship between the size of the second contact hole CH2 and the width of the bias line 16, with reference to FIG. 3B:

a<c<b (1)

The relational expression of Formula (1), however, is not an essential requirement of the present invention. For example, the dimension b of the long axis (major axis b) of the second contact hole CH2 may be equal to or smaller than the width c of the bias line 16.

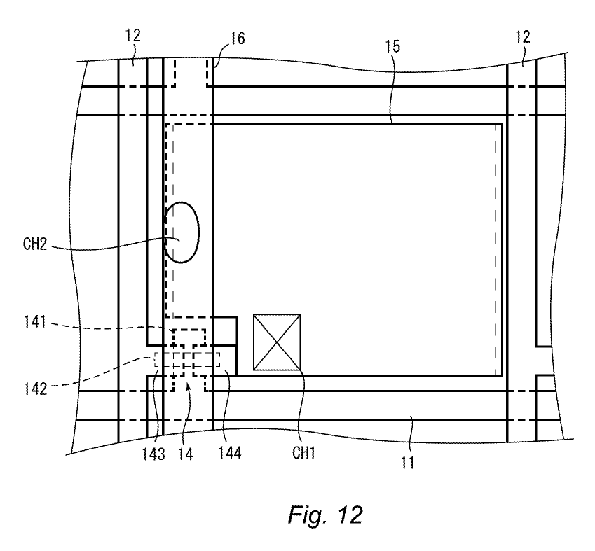

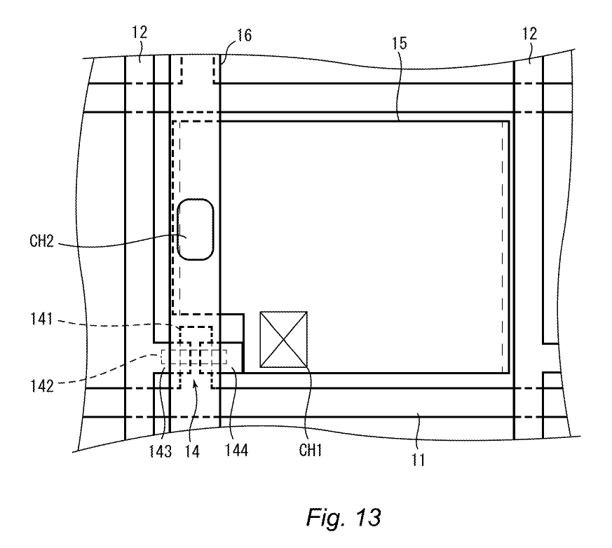

Further, in the description of Embodiment 1, a state is described in which the second contact hole CH2 is arranged at the center in the width direction of the bias line 16, but the second contact hole CH2 may be arranged in such a manner that a part of the edge of the second contact hole CH2 is in contact with one side of the bias line 16, as illustrated in FIG. 12, for example.

In the description of Embodiment 1, a case is described in which the second contact hole CH2 is in an elliptical shape, but it is not an essential requirement that the shape thereof is an elliptical shape. The shape of the second contact hole CH2 can be changed depending on the conditions of the etching and the like. For example, as illustrated in FIG. 13, the second contact hole CH2 may have an approximately rectangular shape having four round corners.

### EMBODIMENT 2

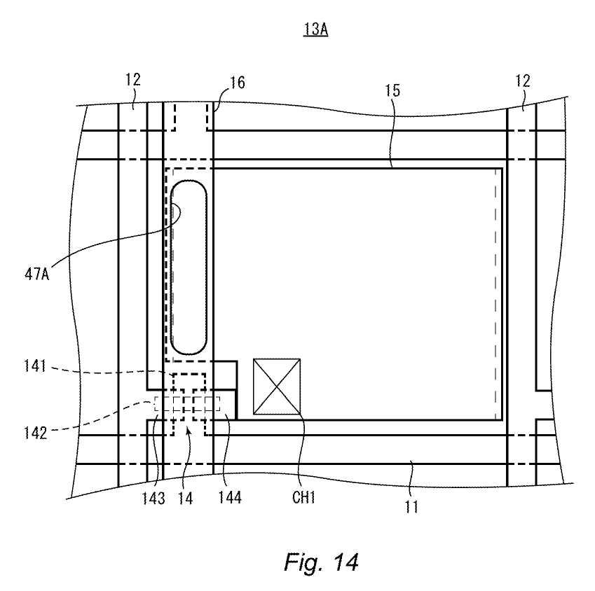

Next, the following describes an X-ray imaging device according to Embodiment 2. FIG. 14 is a plan view illustrating a pixel 13A of an imaging panel of Embodiment 2. The pixel 13A in Embodiment 2 has a configuration different from that in Embodiment 1 in the point that a conductive portion 47A is formed in place of the conductive portion 47 (second contact hole CH2) in the pixel 13 of Embodiment 1.

The conductive portion 47A has a long shape as illustrated in FIG. 14. The width direction of the long shape of the conductive portion 47A coincides with the width direction of the bias line 16. Further, the long shape of the conductive portion 47A extends along the bias line 16. The width of the long shape of the conductive portion 47A is smaller than the width of the bias line 16.

The conductive portion 47A having a long shape as described above allows the area of contact between the electrode 44 and the bias line 16 to be greater in size as compared with the case of Embodiment 1.

### EMBODIMENT 3

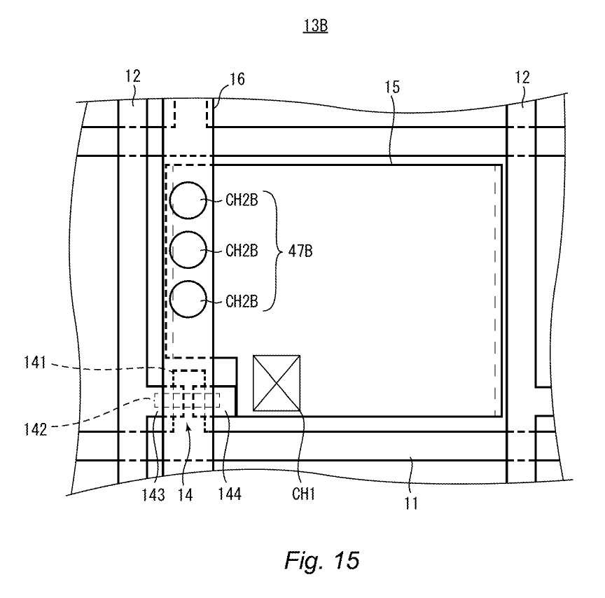

Next, the following describes an X-ray imaging device according to Embodiment 3. FIG. 15 is a plan view illustrating a pixel 13B of an imaging panel of Embodiment 3. The pixel 13B in Embodiment 3 has a configuration different from that in Embodiment 1 in the point that a conductive portion 47B is formed in place of the conductive portion 47 (second contact hole CH2) in the pixel 13 of Embodiment 1.

The conductive portion 47B is composed of a plurality of contact holes CH2B, as illustrated in FIG. 15. A plurality of the contact holes CH2B are arranged so as to be arrayed in the direction in which the bias line 16 extends. The shape of each contact hole CH2B may be circular or elliptical as viewed in the direction of the normal line of the substrate. The conductive portion 47B is thus composed of a plurality of the contact holes CH2B arrayed along the direction in which the bias line 16 extends, whereby the dimension of the conductive portion 47B as a whole in the direction in which the bias line 16 extends is greater than the dimension of the conductive portion 47B in the width direction of the bias line 16. One conductive portion 47B includes, for example, 2 to 4 contact holes CH2B (three in the case illustrated in FIG. 15).

The conductive portion 47B being composed of a plurality of the contact holes CH2B as described above allows a greater area of contact to be ensured between the electrode 44 and the bias line 16.

Furthermore, since the conductive portion 47B is composed of a plurality of the contact holes CH2B, even in a case where the contact state between the electrode 44 and the bias line 16 is poor in one of the contact holes CH2B, the electrode 44 and the bias line 16 can be electrically connected through the other contact holes CH2B.

### Modification Example

The following describes modification examples of the present invention.

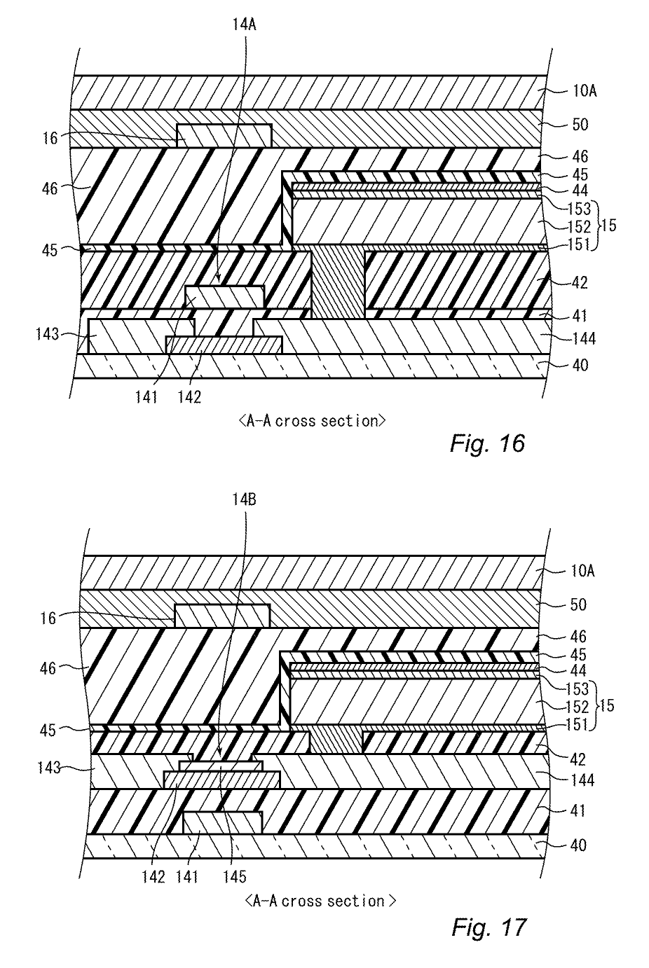

As the above-described embodiments, examples in which the imaging panel 10 includes bottom gate type TFTs 14 are described, but the TFTs 14 may be, for example, top gate type TFTs as illustrated in FIG. 16, or bottom gate type TFTs illustrated in FIG. 17.

Regarding the method for producing the imaging panel that includes the top gate type TFTs 14 illustrated in FIG. 16, points different from the above-described embodiments are described. First, the semiconductor active layer 142 made of an oxide semiconductor is formed on the substrate 40. Then, the source electrodes 143, the data lines 12, and the drain electrodes 144 are formed on the substrate 40 and the semiconductor active layer 142, by laminating titanium, aluminum, and titanium in this order.

Subsequently, the gate insulating film 41 made of silicon oxide (SiOₓ), silicon nitride (SiNₓ), or the like is formed on the semiconductor active layer 142, the source electrodes 143, the data lines 12, and the drain electrodes 144. Thereafter, the gate electrodes 141 and the gate lines 11 are formed on the gate insulating film 41, by laminating aluminum and titanium.

After the formation of the gate electrodes 141, the following steps may be performed: the first interlayer insulating film 42 is formed on the gate insulating film 41 so as to cover the gate electrodes 141, and the first contact holes CH1 that pass through to the drain electrodes 144 are formed; then, as is the case with the above-mentioned embodiments, the photodiodes 15 are formed on the first interlayer insulating film 42 and the drain electrodes 144.

Further, in the case of the imaging panel that includes the TFTs 14 to which the etching stopper layer 145 is provided as illustrated in FIG. 17, the following steps may be performed in the above-described embodiments: after the semiconductor active layer 142 is formed, a film of silicon oxide (SiO₂) is formed on the semiconductor active layer 142 by, for example, plasma CVD or the like; thereafter, the film is patterned by photolithography, whereby the etching stopper layer 145 is formed; then, after the etching stopper layer 145 is formed, the source electrodes 143, the data lines 12, and the drain electrodes 144 are formed by laminating titanium, aluminum, and titanium in this order, on the semiconductor active layer 142 and the etching stopper layer 145.

Embodiments of the present invention described above are merely examples for embodying the present invention. The present invention is not limited by the embodiments described above at all, and can be embodied by making appropriate variations to the above-described embodiments without departing from the scope of the invention.

### INDUSTRIAL APPLICABILITY

The present invention is applicable to an imaging panel and an X-ray imaging device.

1. An imaging panel that generates an image based on scintillation light obtained from X-ray having passed through an object, the imaging panel comprising:
a substrate;
a plurality of conversion elements formed on the substrate, the conversion elements converting the scintillation light into charges;
an insulating film formed so as to cover the conversion elements, the insulating film having a plurality of conductive portions that reach the conversion elements, respectively; and
bias lines formed on the insulating film so as to cover the conductive portions, the bias lines being connected to the conversion elements through the conductive portions, respectively, and supplying a bias voltage to the conversion elements,
wherein a dimension of each of the conductive portions in a direction in which the bias lines extend is greater than a dimension of each of the conductive portions in a width direction of the bias lines.

2. The imaging panel according to claim 1,
wherein each of the conductive portions is formed with a contact hole in an approximately elliptical shape when viewed in a direction of a normal line of the substrate, and
a long axis of the elliptical shape of the contact hole is along the direction in which the bias lines extend, and a short axis of the elliptical shape thereof is along the width direction of the bias lines.

3. The imaging panel according to claim 2,
wherein a dimension of the long axis of the elliptical shape of the contact hole is greater than a width direction dimension of the bias line in which the conductive portion is provided.

4. The imaging panel according to claim 1,
wherein each of the conductive portions is formed with a long opening that extends along the bias lines, and at the same time, has a width smaller than the width of each bias line.

5. The imaging panel according to claim 1,
wherein each of the conductive portions is formed with a plurality of contact holes arranged so as to be arrayed along the direction in which the bias lines extend.

6. An X-ray imaging device comprising:
the imaging panel according to claim 1;
a control unit that reads out a data signal corresponding to charges obtained by conversion by each of the conversion elements;
an X-ray source that emits X-ray; and
a scintillator that convers the X-ray into scintillation light.
